(19) United States
(12) Patent Application Publication
(10) Pub. No.: US 2022/0258303 A1
(43) Pub. Date: Aug. 18, 2022

(54) INSTALLATION AND METHOD FOR POLISHING SEMICONDUCTOR WAFERS

(71) Applicant: SILTRONIC AG, Munich (DE)

(72) Inventors: Jonny FRANKE, Eppendorf (DE); Ludwig LAMPRECHT, Truchtlaching (DE)

(73) Assignee: SILTRONIC AG, Munich (DE)

(21) Appl. No.: 17/618,746

(22) PCT Filed: May 15, 2020
(86) PCT No.: PCT/EP2020/063685

§ 371 Date: Dec. 13, 2021

(30) Foreign Application Priority Data
Jun. 14, 2019 (DE) 10 2019 208 704.3

(51) Int. Cl. B24B 37/34; H01L 21/677; H01L 21/687; B25J 11/00; B24B 37/08; B24B 37/04

(52) U.S. Cl. CPC B24B 37/345; H01L 21/6773; H01L 21/67733; H01L 21/67724; B24B 37/042; H01L 21/67778; B25J 11/0095; B24B 37/08; H01L 21/68707

(57) ABSTRACT

An installation useful for economically polishing wafers has at least two polishing machines for simultaneous double-sided polishing of semiconductor wafers;
one or more carriers lying on a polishing pad of a polishing machine for receiving semiconductor wafers;
an overhead-mounted transport system for delivering a cassette containing semiconductor wafers;
a vertical transport system for taking cassettes from the transport system, containing comprising an integrated wafer lifter;
an autonomous robot having a manipulator for taking a semiconductor wafer from the wafer lifter and for inserting the semiconductor wafer into one of the recesses, and after polishing, for lifting the semiconductor wafer from the recess;
   an x/y linear unit assigned to each polishing machine, having a wafer gripper for taking a wafer from the manipulator and for depositing the wafer into a wet transport container with integrated wafer receiver; and
   a driverless transport vehicle for transporting transport container to a cleaning unit.

### CROSS REFERENCE TO RELATED APPLICATIONS

This application is the U.S. National Phase of PCT Appln. No. PCT/EP2020/063685 filed May 15, 2020, which claims priority to German Application No. 10 2019 208 704.3 filed Jun. 14, 2019, the disclosures of which are incorporated in their entirety by reference herein.

### BACKGROUND OF THE INVENTION

### 1. Field of the Invention

The subject of the invention is an installation for polishing semiconductor wafers which comprises at least two polishing machines for the simultaneous double-sided polishing of semiconductor wafers and which features a high degree of automation. The invention also relates, furthermore, to a method for polishing semiconductor wafers where the installation is used to carry out the method.

### 2. Description of the Related Art

A polishing machine for the simultaneous double-sided polishing of semiconductor wafers, also referred to in this description as a DSP polishing machine, comprises upper and lower polishing plates, each of which is lined with a polishing pad. The semiconductor wafers, as they lie in recesses of carriers, are polished between the polishing plates in the presence of a polishing slurry.

Proposals have already been made to automate the insertion of semiconductor wafers for polishing into the recesses of the carriers and the removal of polished semiconductor wafers from the recesses in the carriers. In this connection mention may be made, for example, of EP 0 931 623 A1, DE 100 07 389 A1 and DE 102 28 441 A1, JP 2005-243 996 A, JP 2005-294378 A, U.S. 6 361 418 B1 and U.S. 2017 0 323 814 A1.

Despite these proposals there continues to be demand for improvements, especially for those whose effects include reducing costs and saving time.

### SUMMARY OF THE INVENTION

These and other objects are achieved by an installation for polishing semiconductor wafershaving at least two polishing machines for the simultaneous double-sided polishing of semiconductor wafers;

one or more carriers which lie on a polishing pad of a respective lower polishing plate of the polishing machines and have recesses for receiving semiconductor wafers; an overhead-mounted transport system for delivering a cassette which contains semiconductor wafers for polishing;
assigned to each of the polishing machines, a vertical transport system for taking the delivered cassette from the overhead-mounted transport system, and comprising an integrated wafer lifter for lifting the semiconductor wafers for polishing out of the cassette;
a robot which moves autonomously to the at least two polishing machines and which has a manipulator for taking the semiconductor wafer for polishing from the wafer lifter, for inserting the semiconductor wafer for polishing into one of the recesses and, at the end of a polishing operation, for lifting the polished semiconductor wafer out of the recess;
assigned to each of the polishing machines, an x/y linear unit having a wafer gripper for taking the polished semiconductor wafer from the manipulator of the autonomously moving robot and for depositing the polished semiconductor wafer into a wet transport container with integrated wafer receiver; and
a driverless transport vehicle for transporting the wet transport container to a cleaning unit for polished semiconductor wafers.

### BRIEF DESCRIPTION OF THE DRAWINGS

FIG. 1 shows one aspect of the invention.

FIG. 2 shows another aspect of the invention.

FIG. 3 shows a vertical transport system of an installation according to the invention.

FIG. 4 shows an x/y linear unit of an installation according to the invention.

### DETAILED DESCRIPTION OF THE PREFERRED EMBODIMENTS

in addition to the polishing installation described above, a further subject of the invention is a method for polishing semiconductor wafers, comprising providing at least two polishing machines for the simultaneous double-sided polishing of semiconductor wafers;

delivering semiconductor wafers for polishing in a cassette by means of an overhead-mounted transport system;
lifting a centred semiconductor wafer for polishing out of the cassette by means of a wafer lifter of a vertical transport system;
taking one of the semiconductor wafers for polishing from the wafer lifter of the overhead-mounted transport system or from a centering station by a manipulator of an autonomously moving robot;
inserting the semiconductor wafer for polishing into a recess of a carrier of the at least two polishing machines by the manipulator of the autonomously moving robot;
removing a polished semiconductor wafer from one of the recesses of the carriers by means of the manipulator of the autonomously moving robot;
taking the polished semiconductor wafer from the manipulator of the autonomously moving robot by a wafer gripper of an x/y linear unit;
depositing the polished semiconductor wafer into a wafer receiver of a wet transport container by the wafer gripper;
transferring the wet transport container from the x/y linear unit to a driverless transport vehicle; and

transporting the wet transport container by means of the driverless transport vehicle to a cleaning unit for polished semiconductor wafers.

The invention permits the fully automatic, space-saving and cost-saving design of the operation, from the delivery of semiconductor wafers for polishing through to the transport of the semiconductor wafers after polishing to a cleaning unit. The semiconductor wafers are preferably monocrystalline silicon semiconductor wafers, more preferably those having a diameter of at least 200 mm.

The provisions of the invention include having at least two polishing machines for the simultaneous double-sided polishing of semiconductor wafers being loaded with semiconductor wafers and unloaded by an autonomously moving robot. The number of DSP polishing machines assigned to the autonomously moving robot is preferably optimized in accordance with the duration of the polishing operation. Provided preferably are at least 3 to 10, more preferably at least 3 to 6, DSP polishing machines actuated by the same autonomously moving robot. This solution saves on the costs which would arise if a separate robot was provided for each of the polishing machines. Correspondingly, the space requirement is also smaller. The autonomously moving robot takes semiconductor wafers for polishing from a wafer lifter (wafer lift-out) of a vertical transport system or from a centering station. Each of the DSP polishing machines is assigned one such vertical transport system. Semiconductor wafers for polishing are stacked in a cassette, which an overhead-mounted transport system (overhead hoist transport, OHT) delivers to a DSP polishing machine for the loading of the latter. The cassettes used may be open or closed, examples being those known as FOUPs. Open cassettes, being cassettes without a front door, are preferred if the semiconductor wafers for polishing are stacked standing vertically therein. By virtue of its construction, an open cassette of this kind enables direct access to the semiconductor wafers as soon as the open cassette has been placed down by the OHT on a cassette receiver of the vertical transport system and has been lowered by the vertical transport system to the wafer lifter up to an end position. In the end position, the semiconductor wafers for polishing stand in grooves of a wafer receiver of the wafer lifter and are supported laterally by grooves of a guide of the vertical transport system. By virtue of this arrangement, the vertical transport system possesses an inherent centering function, meaning that the semiconductor wafers for polishing are located standing in a centered state on the wafer lifter. The significance of this is that a semiconductor wafer for polishing is already made available for transfer to the autonomously moving robot, in such a way that a manipulator of the autonomously moving robot is able to suction the semiconductor wafer in the center without having itself to ascertain the center of the wafer beforehand or without any need for a centering station, in which the semiconductor wafer for polishing would have to be centered before being transferred to the autonomously moving robot. The absence of a stand-alone centering station is likewise cost-saving and space-saving, and accelerates the loading procedure, since there is no requirement for the manipulator of the autonomously moving robot to transport the semiconductor wafer, in multiple steps, first from the cassette, then into the centering station and subsequently into the recess of the carrier.

This notwithstanding, there is no intention to rule out the provision of a centering station, for example a centering ring, into which the semiconductor wafer for polishing is deposited by the wafer lifter of the vertical transport system. The provision of such a station is useful especially when semiconductor wafers for polishing are delivered from the overhead-mounted transport system horizontally in a FOUP. In that case, one of the semiconductor wafers for polishing is removed from the FOUP by the wafer lifter of the vertical transport system and is first deposited in the centering station, before being received in a centered state by the manipulator of the autonomously moving robot.

The autonomously moving robot is designed as a driverless vehicle (automated guided vehicle, AGV) or is mounted on and controls the movements of an AGV. The autonomously moving robot preferably travels on wheels. It comprises an arm, with a manipulator for semiconductor wafers attached to the end of the arm, and also an optical recognition system, preferably a camera. This camera is used to recognise markings on carriers of the polishing machines, preferably markings on the surface of the carriers. On the basis of the placement of the markings, the robot computes the position of the center of a recess. Further cameras are not provided for this purpose. The manipulator preferably comprises a device for suctioning a semiconductor wafer on one of its two side faces. The manipulator takes a semiconductor wafer for polishing in the centered state from the wafer lifter of the vertical transport system or from the centering station.

The autonomously moving robot then begins the loading of the DSP polishing machine, which is in a waiting state for loading. By means of the camera, the autonomously moving robot ascertains the position of the center of a free recess in a carrier of the DSP polishing machine to be loaded, and places the semiconductor wafer for polishing into the free recess. The procedure, from the lifting of a semiconductor wafer for polishing by the wafer lifter of the vertical transport system through to the insertion of the semiconductor wafer for polishing into a free recess in a carrier of the DSP polishing machine by the manipulator of the autonomously moving robot, is repeated until the DSP polishing machine is loaded with an intended number of semiconductor wafers for polishing. The procedure is generally at an end when the recesses in the carriers of the polishing machine that are present for the purpose of receiving semiconductor wafers have been populated with semiconductor wafers for polishing. After the end of loading, polishing is commenced through a signal from the autonomously moving robot, with the upper polishing plate being lowered against the lower polishing plate and closed. During the polishing of these semiconductor wafers, the autonomously moving robot loads another of the polishing machines with semiconductor wafers for polishing, or unloads polished semiconductor wafers from another of the polishing machines.

Preference is given in particular to the polishing of some of the semiconductor wafers provided to the installation on at least one of the polishing machines, while the autonomously moving robot takes one of the semiconductor wafers of some other of these semiconductor wafers from the wafer lifter of the vertical transport system or from the centering station, or inserts it into one of the recesses or removes it from one of the recesses.

For the unloading procedure, each of the polishing machines is assigned an x/y linear unit, which allows a polished semiconductor wafer to be transported in at least two of three spatial directions. The x/y linear unit comprises a wafer gripper having end effectors, which grip the polished semiconductor wafers at the edges without damage.

After the end of the polishing operation, the polished semiconductor wafers are suctioned successively by the manipulator of the autonomously moving robot from the recesses in the carriers, are transferred to the wafer gripper of the x/y linear unit, and are subsequently sorted into a wet transport container with integrated wafer receiver. For this purpose, the wafer gripper with end effectors has a very narrow design, preferably such that it fits into a slot with a width of not more than 5 mm. The wafer receiver of the wet transport container possesses a number of slots, into each of which a polished semiconductor wafer can be deposited with vertical positioning. Following the removal of a polished semiconductor wafer from a recess in a carrier by the manipulator on the arm of the autonomously moving robot, the wafer gripper of the x/y linear unit, with its end effectors, takes the polished semiconductor wafer from the autonomously moving robot. Because, from this moment, the responsibility for the polished semiconductor wafer is taken from the autonomously moving robot, the duration of the unloading procedure is less than if the robot continued to have responsibility.

Next, the x/y linear unit transports the polished semiconductor wafer by means of the wafer gripper over the liquid-filled wet transport container, and pushes the semiconductor wafer from above into a free slot of the wafer receiver of the wet transport container. Following the release of the polished semiconductor wafer by the end effectors and the retreat of the wafer gripper, the semiconductor wafer stands vertically in the wafer receiver of the wet transport container and is surrounded by the liquid in the wet transport container. At least that surface of the wet transport container that is in contact with the liquid consists preferably of a chemically resistant material, resistant both to basic and to acid-containing media.

In order to prevent chemical reactions or physical alterations occurring on the surfaces of the polished semiconductor wafers, after a polishing operation, preferably all of the polished semiconductor wafers are unloaded from a DSP polishing machine by the autonomously moving robot, before the autonomously moving robot loads another of the DSP polishing machines with semiconductor wafers for polishing or unloads polished semiconductor wafers from another DSP polishing machine.

The unloading of a polished semiconductor wafer from the recess in a carrier takes place in analogy to the loading of a semiconductor wafer for polishing. The polished semiconductor wafer is suctioned with the manipulator on the arm of the autonomously moving robot, on the polished upper side face, and lifted from the recess. The memory of the robot usefully contains information on those recesses in the carriers that are populated with semiconductor wafers, especially the positions of the centers of the semiconductor wafers.

The wet transport container, which preferably can be filled with and emptied of liquid automatically, is transferred automatically, with the polished semiconductor wafers contained therein, to an AGV, for example by means of belt, roller or linear conveying, and is moved by the AGV autonomously and freely in space, with automatic navigation, to a cleaning unit for polished semiconductor wafers, where the wet transport container is handed over automatically and is coupled preferably via an adapter which is mounted on the end face of the wet transport container. The operation of this AGV does not require an accompanying robot. With preference the same AGV is assigned to a plurality of the DSP polishing machines for collecting and providing the wet transport containers; for example, one AGV for up to ten DSP polishing machines, more preferably one AGV for those DSP polishing machines for which the autonomously moving robot has responsibility.

The invention is explained more below with reference to drawings.

List of Reference Numerals Used

1 Installation for polishing semiconductor wafers

2 DSP polishing machine

3 Lower polishing plate

4 Carrier

5 Recess

6 Semiconductor wafer

7 Autonomously moving robot

8 OHT

9 x/y linear unit

10 Wet transport container

11 AGV

12 Cleaning unit

13 Vertical transport system

14 Cassette receiver

15 Wafer lifter

16 Guide

17 Wafer gripper

18 End effector

19 Bar

20 Centring station

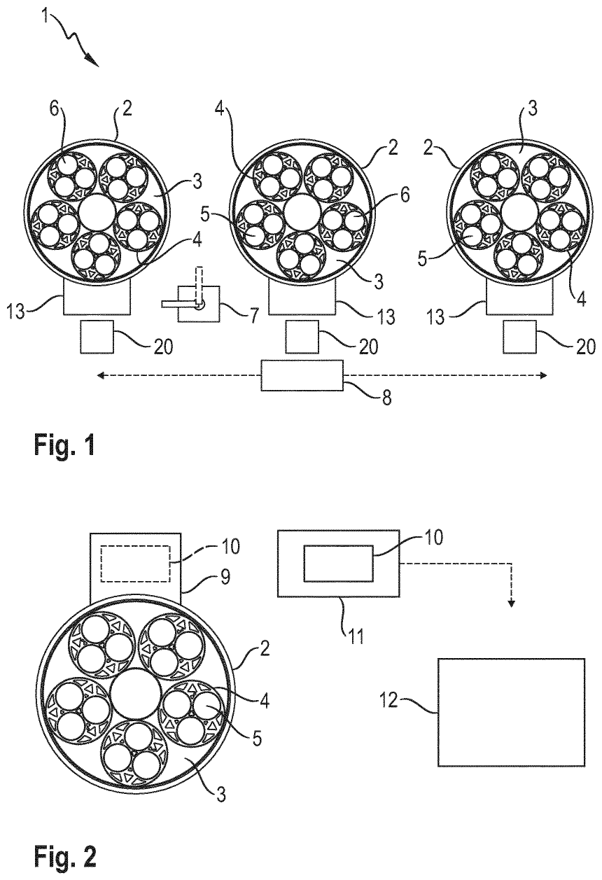

The installation 1 according to the invention shown in FIG. 1, for polishing of semiconductor wafers, to be understood as an example, comprises three DSP polishing machines 2, the lower polishing plates 3 of which are depicted in plan view. Lying on the lower polishing plates are carriers 4 with recesses 5 for semiconductor wafers 6. The DSP polishing machine arranged on the left is in operation, and all of the recesses 5 in the carriers 4 are populated with semiconductor wafers 6 for polishing. The closed upper polishing plate of this DSP polishing machine and the opened upper polishing plates of the two other DSP polishing machines are not shown. The middle DSP polishing machine 2 has a partial loading of semiconductor wafers 6 for polishing, whereas the DSP polishing machine 2 arranged on the right is in the unloaded state.

For loading and unloading, a single, autonomously moving robot 7 is assigned to the DSP polishing machines 2. In the representation in FIG. 1, the autonomously moving robot 7 is busy placing semiconductor wafers 6 for polishing into the remaining free recesses 5 in the carriers 4 of the middle DSP polishing machine 2. For this purpose, a manipulator mounted on the arm of the robot takes a semiconductor wafer 6 for polishing from the vertical transport system 13 or from the centring station 20. Semiconductor wafers for polishing are delivered to the vertical transport system 13 by an OHT 8, in a cassette which is preferably of open configuration and which contains semiconductor wafers for polishing standing vertically. The autonomously moving robot 7 transports the semiconductor wafer 6, taken from the wafer lifter of the vertical transport system 13 or from the centering station 20, to the middle DSP polishing machine 2, and places it into one of the free recesses 5 in the carriers 4 of that machine. The procedure will be repeated until the middle DSP polishing machine 2 is fully loaded with semiconductor wafers 6 for polishing.

Assigned to each of the DSP polishing machines 2 is an x/y linear unit 9, not shown in FIG. 1. FIG. 2 shows the DSP polishing machine 2 arranged on the right, and the x/y linear unit 9 assigned to it. Semiconductor wafers 6 which have been polished on this polishing machine 2 have been lifted out of the recesses 5 in the carriers 4 by the manipulator of the autonomously moving robot 7, taken from the x/y linear unit 9 and deposited into wafer receivers of a wet transport container 10. According to the representation in FIG. 2, the wet transport container 10 with the polished semiconductor wafers 6 has been transferred from the x/y linear unit 9 onto an AGV 11, and is being transported by the AGV 11 to a cleaning unit 12 for polished semiconductor wafers 6. At the same moment, the autonomously moving robot 7 is busy placing semiconductor wafers 6 for polishing into the remaining free recesses 5 in the carriers 4 of the middle DSP polishing machine 2.

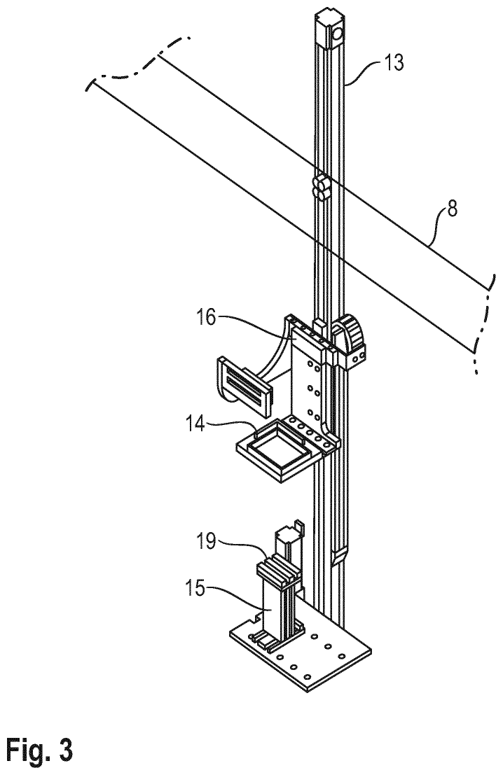

Assigned to each of the DSP polishing machines is a vertical transport system 13—for example, the preferred vertical transport system 13 shown in FIG. 3. This vertical transport system 13 comprises a cassette receiver 14, on which a delivered open cassette with semiconductor wafers for polishing is placed down by the OHT 8. The cassette receiver 14 can be raised and lowered vertically from a height in the region of the OHT to a height in the region of the lower polishing plate of the DSP polishing machine, by means of a carriage. The vertical transport system 13 further comprises a wafer lifter 15 with defined position and guides 16 for the lateral supporting of semiconductor wafers for polishing. When an open cassette (not shown) placed down on the cassette receiver 14 is lowered to an end position, semiconductor wafers for polishing that are contained in the open cassette are lifted by the wafer lifter 15 out of the open cassette and thereafter, by virtue of the defined position of the wafer lifter 15, are in a centred state in grooves of bars 19 of the wafer lifter 15, and supported laterally by guides 16. The guides 16 likewise have grooves for receiving the edges of the semiconductor wafers for polishing. In this centred state, the semiconductor wafers for polishing are taken successively by the manipulator of the autonomously moving robot, by being suctioned in the centre of one side face. The wafer lifter 15 is preferably equipped with at least one measuring unit, which establishes the number of semiconductor wafers delivered, verifies this number for plausibility, and transmits this information as a control signal to the autonomously moving robot. The vertical transport system 13 also possesses an independently functioning control for the vertical movement, which ensures a steplessly tuneable movement profile, specifically of the speeds. The constructional design of the vertical transport system also enables subsequent mounting of the vertical transport system 13 onto a DSP polishing machine, without the need to have to undertake extensive modifications of the DSP polishing machine.

As an alternative to this, the cassette receiver may be configured to be able to receive a FOUP, and the wafer lifter may additionally possess a FOUP opener.

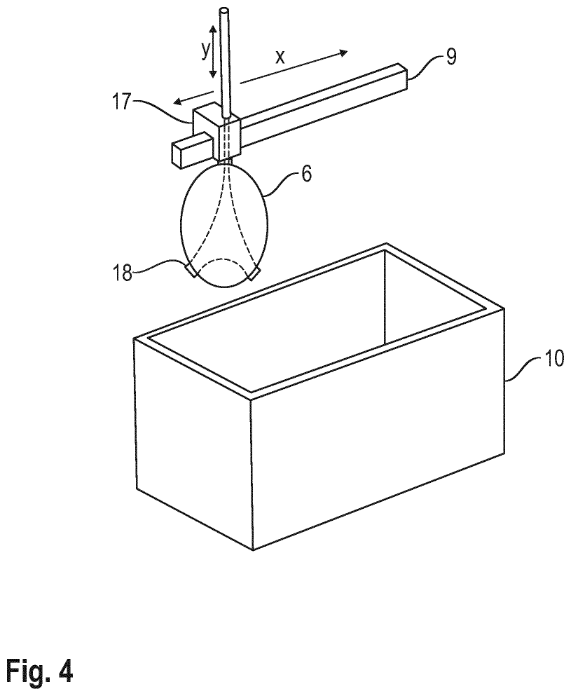

Also assigned to each of the DSP polishing machines is an x/y linear unit—for example, the x/y linear unit 9 shown in FIG. 4. The x/y linear unit 9 comprises a wafer gripper 17 with end effectors 18 for taking a polished semiconductor wafer from the manipulator of the self-driving robot. The end effectors 18 hold the semiconductor wafer at its edge.

The above description of exemplary embodiments should be understood to be by way of example. The disclosure thus made firstly enables the skilled person to comprehend the present invention and the associated advantages, and secondly, within the understanding of the skilled person, also encompasses obvious alterations and modifications to the structures and methods described. Therefore, all such alterations and modifications, and also equivalents, are to be covered by the scope of protection of the claims.

1.-6. (canceled)

7. An installation for polishing semiconductor wafers, comprising at least two polishing machines for the simultaneous double-sided polishing of semiconductor wafers;
one or more carriers which lie on polishing pads of respective lower polishing plates of the polishing machines and have recesses for receiving semiconductor wafers;
an overhead-mounted transport system for delivering a cassette which contains semiconductor wafers for polishing;
assigned to each of the polishing machines, a vertical transport system for taking the delivered cassette from the overhead-mounted transport system, and comprising an integrated wafer lifter for lifting the semiconductor wafers for polishing out of the cassette;
a robot which moves autonomously to the at least two polishing machines and which has a manipulator for taking the semiconductor wafer for polishing from the wafer lifter, for inserting the semiconductor wafer for polishing into one of the recesses and, at the end of a polishing operation, for lifting the polished semiconductor wafer out of the recess;
assigned to each of the polishing machines, an x/y linear transporter having a wafer gripper for taking the polished semiconductor wafer from the manipulator of the autonomously moving robot and for depositing the polished semiconductor wafer into a wet transport container with an integrated wafer receiver; and
a driverless transport vehicle for transporting the wet transport container to a cleaning unit for polished semiconductor wafers.

8. The installation of claim 7, wherein the cassettes are open cassettes.

9. The installation of claim 7, having from 3 to 10 polishing machines.

10. The installation of claim 8, having from 3 to 10 polishing machines.

11. The installation of claim 7, wherein the wafer gripper possesses end effectors which hold the semiconductor wafer at a wafer edge and which dip between slots of the wafer receiver of the wet transport container.

12. A method for polishing semiconductor wafers using an installation of claim 7, comprising:
providing at least two polishing machines for the simultaneous double-sided polishing of semiconductor wafers;
delivering semiconductor wafers for polishing in a cassette by means of an overhead-mounted transport system;
lifting a semiconductor wafer for polishing out of the cassette by means of a wafer lifter of a vertical transport system;
taking one of the semiconductor wafers for polishing from the wafer lifter of the vertical transport system or from a centering station by a manipulator of an autonomously moving robot;
inserting the semiconductor wafer for polishing into a recess of a carrier of one of the at least two polishing machines by the manipulator of the autonomously moving robot;
removing a polished semiconductor wafer from one of the recesses of the carriers by means of the manipulator of the autonomously moving robot;
taking the polished semiconductor wafer from the manipulator of the autonomously moving robot by a wafer gripper of an x/y linear transporter;
depositing the polished semiconductor wafer into a wafer receiver of a wet transport container by the wafer gripper;
transferring the wet transport container from the x/y linear unit to a driverless transport vehicle; and
transporting the wet transport container by means of the driverless transport vehicle to a cleaning unit for polished semiconductor wafers.

13. The method of claim 12, further comprising the polishing of some of the semiconductor wafers on at least one of the polishing machines, while the autonomously moving robot takes one of the semiconductor wafers of some other of the semiconductor wafers, and inserts it into one of the recesses or removes it from one of the recesses.
